(19) United States
(12) Patent Application Publication
(10) Pub. No.: US 2010/0001371 A1
(43) Pub. Date: Jan. 7, 2010

(54) SEMICONDUCTOR DEVICE HAVING CAPACITOR INCLUDING A HIGH DIELECTRIC FILM AND MANUFACTURE METHOD OF THE SAME

(75) Inventors: Tatsuya SUZUKI, Kyoto (JP); Yoshikazu FUJIMORI, Kyoto (JP); Tsuyoshi FUJII, Kyoto (JP)

Correspondence Address: CANTOR COLBURN, LLP, 20 Church Street, 22nd Floor, Hartford, CT, 06103, US

(73) Assignee: ROHM CO., LTD., Kyoto-fu (JP)

(21) Appl. No.: 12/328,843

(22) Filed: Dec. 5, 2008

(30) Foreign Application Priority Data
Dec. 5, 2007 (JP) P2007-314691

(51) Int. Cl. H01L 29/92; H01L 21/02

(52) U.S. Cl. 257/532; 438/381; 257/E29.343; 257/E21.008

(57) ABSTRACT

A semiconductor device includes a substrate, a plurality of lower electrodes arranged on the substrate, a high dielectric film disposed continuously on the plurality of lower electrodes, and an upper electrode disposed on the high dielectric film.

### CROSS REFERENCE TO RELATED APPLICATIONS AND INCORPORATION BY REFERENCE

This application is based upon and claims the benefit of priority from prior Japanese Patent Application P2007-314691 filed on Dec. 5, 2007; the entire contents of which are incorporated by reference herein.

### BACKGROUND OF THE INVENTION

1. Field of the Invention

The present invention relates to a semiconductor device having capacitor including a high dielectric film and a method for manufacturing the same.

2. Description of the Related Art

A capacitor with a configuration in which a high dielectric film is disposed between electrodes (hereinafter, referred to as a “high dielectric capacitor”) is used as a capacitor composing a pixel of a display device and the like, or composing a memory cell of a nonvolatile memory and the like. For such a high dielectric for use in the high dielectric capacitor, a material is used, which has hysteresis excellent in rectangularity ratio, in which a residual dielectric polarization is large, and a coercive electric field is small. Specifically, a high dielectric capacitor is adopted, which has a structure in which a high dielectric film, for example, such as a lanthanum-doped lead zirconate titanate (PLZT) film is disposed between an upper electrode and a lower electrode.

In manufacture of the high dielectric capacitor, the lower electrode, the high dielectric film and the upper electrode are stacked on one another, and the upper electrode, the high dielectric film and the lower electrode are thereafter etched, whereby device isolation has been carried out so as to obtain one pixel or one memory cell. However, in the above-described manufacture method of the high dielectric capacitor, the device isolation is carried out by isolating the high dielectric film, and accordingly, large step differences occur, and it is difficult to planarize a surface of the obtained device. Moreover, there has been a problem that device isolation regions are widened, causing difficulty in fine isolation. In particular, in the case of optically using the high dielectric capacitor formed by the above-described method, the high dielectric film is isolated, and accordingly, a distance between the pixels is large, and the step differences are large. Therefore, in the high dielectric capacitor, an aperture ratio and a diffraction efficiency are decreased.

### SUMMARY OF THE INVENTION

An aspect of the present invention is a semiconductor device includes a substrate; a plurality of lower electrodes arranged on the substrate; a high dielectric film disposed continuously on the plurality of lower electrodes; and an upper electrode disposed on the high dielectric film.

Another aspect of the present invention is a method for manufacturing a semiconductor device. The method includes forming a lower electrode layer on a substrate; dividing the lower electrode layer into a plurality of lower electrodes; forming a high dielectric film continuously on the plurality of lower electrodes; and forming an upper electrode on the high dielectric film.

### BRIEF DESCRIPTION OF THE DRAWINGS

FIG. 1 is a schematic cross-sectional view showing a semiconductor device according to a first embodiment of the present invention.

FIG. 2 is a schematic cross-sectional view showing a semiconductor device of the related art.

FIG. 3 is a schematic plan view of a reflective light modulation device using the semiconductor device according to the first embodiment of the present invention.

FIG. 4 is a cross-sectional view along a direction IV-IV of FIG. 3.

FIGS. 5A and 5B are an example of using the semiconductor device according to the first embodiment of the present invention for the reflective light modulation device:

FIG. 5A is a photograph of an upper surface of the reflective light modulation device; and FIG. 5B is a cross-sectional photograph along a direction VB-VB of FIG. 5A.

FIGS. 6A to 6C are an example of using the semiconductor device of the related art for the reflective light modulation device: FIG. 6A is a photograph of an upper surface of the reflective light modulation device; FIG. 6B is a cross-sectional photograph along a direction VIB-VIB of FIG. 6A; and FIG. 6C is a cross-sectional photograph along a line VIC-VIC of FIG. 6A.

FIGS. 7A and 7B are photographs for explaining that an aperture ratio is enhanced by using the semiconductor device according to the first embodiment of the present invention for the reflective light modulation device: FIG. 7A is a photograph of an upper surface of the reflective light modulation device using the semiconductor device according to the first embodiment of the present invention; and FIG. 7B is a photograph of an upper surface of the reflective light modulation device using the semiconductor device of the related art.

FIGS. 8A and 8B are photographs showing diffraction patterns of the reflective light modulation device: FIG. 8A is a photograph showing a diffraction pattern of the reflective light modulation device using the semiconductor device according to the first embodiment of the present invention; and FIG. 8B is a photograph showing a diffraction pattern of the reflective light modulation device using the semiconductor device of the related art.

FIG. 9 is a graph showing ratios of diffraction light with respect to total reflected light in the reflective light modulation device using the semiconductor device according to the first embodiment of the present invention.

FIG. 10 is a schematic circuit diagram of a nonvolatile memory using the semiconductor device according to the first embodiment of the present invention.

FIG. 11 is a schematic plan view of the nonvolatile memory using the semiconductor device according to the first embodiment of the present invention.

FIGS. 12 to 15 are process cross-sectional views for explaining an example of a manufacture method of the semiconductor device according to the first embodiment of the present invention.

FIG. 16 is a schematic cross-sectional view showing a semiconductor device according to a second embodiment of the present invention.

FIGS. 17A and 17B are a photograph showing an example of a crack that occurred in a PLZT film, and a cross-sectional view of the PLZT film.

FIGS. 18 and 19 are process sectional-views for explaining an example of a manufacture method of the semiconductor device according to the second embodiment of the present invention.

FIG. 20 is an example of a cross-sectional photograph of the semiconductor device according to the second embodiment of the present invention.

FIG. 21 is a schematic cross-sectional view showing a semiconductor device according to a modification example of the second embodiment of the present invention.

### DETAILED DESCRIPTION OF THE INVENTION

An embodiment of the present invention will be described with reference to the accompanying drawings. In the following description of the drawings, the same or similar reference numerals are applied to the same or similar parts and elements. It is to be noted that the drawings are schematic and have different relationship between thickness and planer dimensions, proportions of thickness of layers, and the like from the real ones. Accordingly, specific thicknesses and dimensions should be determined with reference to the following description. Moreover, it is obvious that some parts have different dimensional relationships or proportions throughout the drawings.

The following embodiment just shows devices and methods to embody the technical idea of the present invention, and the technical idea of the present invention does not specify materials, shapes, structures, and arrangements of the constituent components and the like to the following description. The technical idea of the present invention can be variously modified in the scope of claims.

### First Embodiment

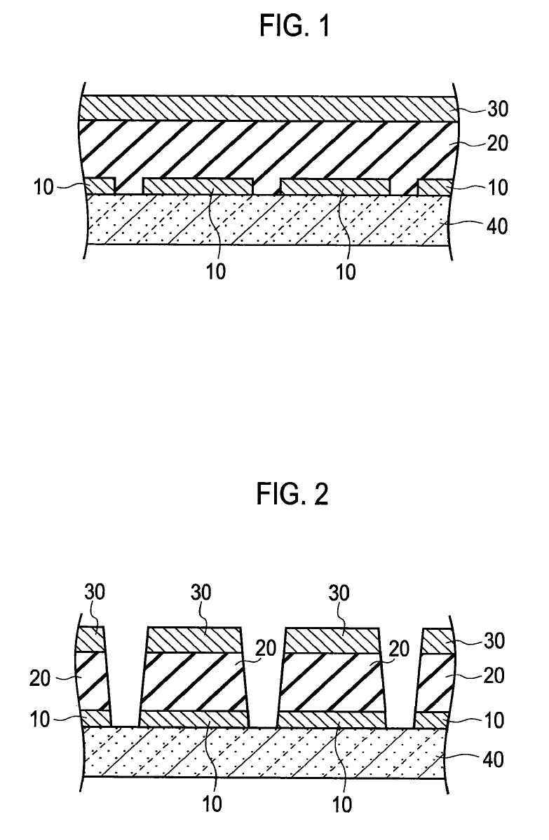

As shown in FIG. 1, a semiconductor device according to a first embodiment of the present invention includes: a substrate 40; a plurality of lower electrodes 10 arranged on the substrate 40; a high dielectric film 20 disposed continuously on the plurality of lower electrodes 10; and an upper electrode 30 disposed on the high dielectric film 20. In the semiconductor device shown in FIG. 1, each of the plurality of lower electrodes 10 and the upper electrode 30 opposite thereto while interposing the high dielectric film 20 therebetween compose a single high dielectric capacitor.

In the semiconductor device shown in FIG. 1, regions among the lower electrodes 10 arranged on the same plane while being spaced from one another at an interval are filled with the high dielectric film 20, and an upper surface of the high dielectric film 20 is flat. Therefore, the upper electrode 30 is also disposed while maintaining flatness thereof, whereby an upper surface of the semiconductor device shown in FIG. 1 is flat.

For the high dielectric film 20, a material is adoptable, in which a polarization state that occurred at the time of being applied with an electric field is held even after such application of the electric field was ended, and an orientation of the polarization is changed by a direction of an electric field from the outside. In particular, for the high dielectric film 20, a material such as a ferroelectric film is suitable, which has hysteresis excellent in rectangularity ratio, in which a residual dielectric polarization is large, and a coercive electric field is small. Specifically, as the high dielectric film 20, for example, adoptable are: a lanthanum-doped lead zirconate titanate (PLZT) film; a barium strontium titanate (BST) film; a lead zirconate titanate (PZT) film; a strontium bismuth tantalate (SBT) film; a strontium barium niobate (SBN) film; a lithium niobate (LiNbO₃) film; a barium titanate (TiBaO₃) film; a lanthanum strontium copper oxide (LSCO) film; a potassium dihydrogen phosphate (KDP) film; a potassium tantalum niobate (KTN) film; a lead magnesium niobate-lead titanate (PMN-PT) ceramic film; a lead zinc niobate-lead titanate (PZN-PT) ceramic film; and the like.

For the substrate 40, for example, a silicon (Si) substrate, a quartz substrate and the like are adoptable.

As an example of the related art, FIG. 2 shows a cross section of a semiconductor device subjected to device isolation in such a manner that the upper electrode 30, the high dielectric film 20 and the lower electrode 10 are etched continuously after the lower electrode 10, the high dielectric film 20 and the upper electrode 30 are stacked on the substrate 40. As shown in FIG. 2, in the case where the upper electrode 30 and the high dielectric film 20 are also etched for the purpose of the device isolation, a thickness of such stacked films subjected to the etching becomes thick, and large step differences occur.

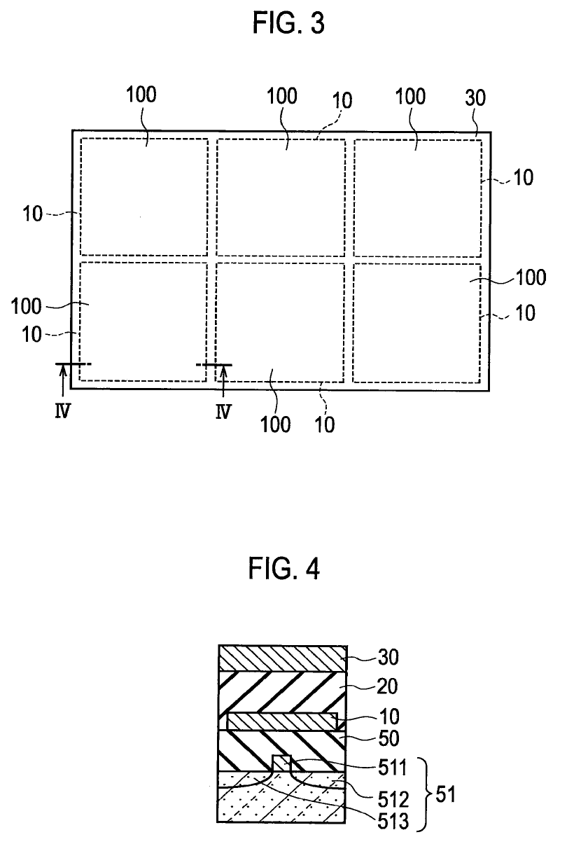

FIG. 3 shows an example of optically using the high dielectric capacitor shown in FIG. 1 and applying the high dielectric capacitor to a spatial light modulator. FIG. 3 is a plan view of a reflective light modulation device, in which the high dielectric capacitors are arranged in a matrix pattern, and each of the high dielectric capacitors functions as a single pixel 100. In FIG. 3, the lower electrodes 10 arranged below the upper electrode 30 are shown by broken lines. FIG. 3 shows the case where the number of pixels 100 is six in an illustrative manner; however, it is a matter of course that the number of pixels is not limited to six. For example, it is possible to form a reflective light modulation device in which the pixels 100 with an area of 25 μm×25 μm are arranged in a pattern of 180 pieces×180 pieces.

The high dielectric film 20 has an electrooptical effect that a refractive index is changed in response to the electric field applied thereto. Accordingly, light made incident onto the reflective light modulation device shown in FIG. 3 from the upper electrode 30 side is reflected in response to the refractive index of the high dielectric film 20 for each of the pixels 100. Then, the light in which intensity and phase are modulated is outputted from the upper electrode 30. As the upper electrode 30, a transparent electrode is adoptable, which is made of, for example, platinum (Pt), iridium (Ir), iridium oxide (IrOₓ), strontium ruthenate (SRO), indium tin oxide (ITO), zinc oxide (ZnO) and the like. For the lower electrode 10, for example, Pt, Ir and the like are adoptable.

In the reflective light modulation device shown in FIG. 3, a potential of the upper electrode 30 is common among the respective pixels 100. Therefore, the refractive index of the high dielectric film 20 for each of the pixels 100 is controlled by a voltage applied to each of the lower electrodes 10. Specifically, it is possible to control the refractive index by the voltage applied to each of the lower electrodes 10 independently for each of the pixels 100, and it is not necessary to dispose, for each of the pixels 100, an electric wire for applying the voltage to the upper electrode 30.

FIG. 4 shows a cross-sectional structure of the pixel 100 shown in FIG. 3. As shown in FIG. 4, in the reflective light modulation device shown in FIG. 3, it is possible to dispose a drive element 51 that applies the voltage to the lower electrode 10 for the purpose of controlling the refractive index of the pixel 100 below each of the pixels 100 while sandwiching an interlayer insulating film 50 therebetween. Therefore, though not shown, an electric wire that connects the drive element 51 and the pixel 100 to each other can be formed immediately below the lower electrode 10 of each of the pixels 100. Moreover, as already described, the electric wire to be connected to the upper electrode 30 is not necessary for each of the pixels 100, and accordingly, the electric wires to be connected to the upper electrodes 30 can be formed in a peripheral region of the reflective light modulation device. Hence, it is not necessary to arrange, among the pixels 100, the wires for controlling the refractive indices of the pixels 100. As a result, an interval among the pixels 100 can be narrowed in comparison with the case of arranging, among the pixels 100, the wires to be connected to the upper electrodes 30. A width of device isolation regions among the pixels 100 is, for example, approximately 1 μm.

Note that, for the drive element 51, for example as shown in FIG. 4, it is possible to adopt a field effect transistor including a gate electrode 511, a source electrode 512 and a drain electrode 513. Moreover, it is possible to dispose the wire for controlling the drive element 51 in the interlayer insulating film 50, and a control circuit that controls the drive element 51 is disposed, for example, in the peripheral region of the reflective light modulation device.

In the reflective light modulation device shown in FIG. 3 and FIG. 4, only the lower electrode 10 is isolated for the purpose of the device isolation. Specifically, the isolation of the upper electrode 30 and the isolation of the high dielectric film 20, which are as shown in FIG. 2, are not performed. Accordingly, no step differences occur among the pixels 100, and the interval among the pixels is not widened.

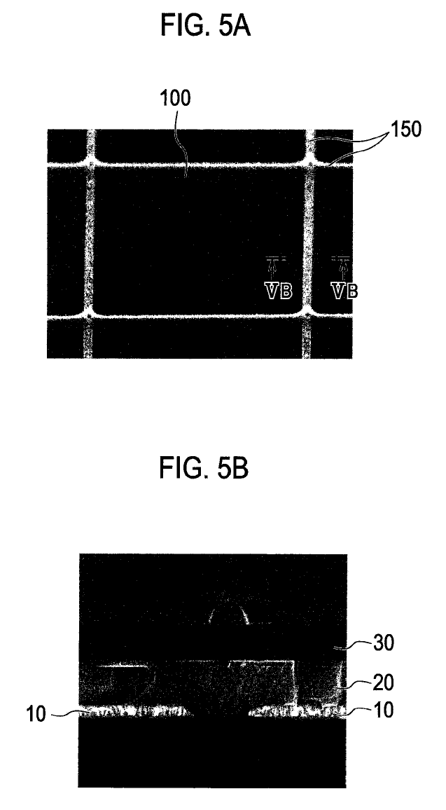

FIGS. 5A and 5B show photograph examples of an upper surface of the reflective light modulation device shown in FIG. 3 and of a cross section of the device isolation region thereof, which is taken by an electron microscope. FIG. 5B is a cross-sectional photograph in a direction VB-VB of the device isolation region 150 shown in FIG. 5A. As shown in FIG. 5B, the region between the lower electrodes 10 is filled with the high dielectric film 20, and the upper surface of the high dielectric film 20 is flat.

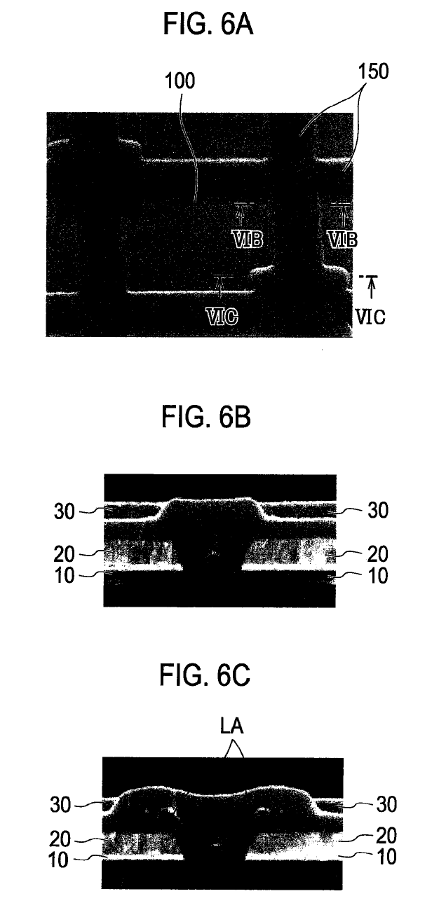

Moreover, as an example of the related art, FIGS. 6A, 6B and 6C show photographs of an upper surface of the reflective light modulation device subjected to the device isolation by continuously etching the upper electrode 30, the high dielectric film 20 and the lower electrode 10 and of a cross section of the device isolation region 150 thereof. FIG. 6C also shows a wire LA that is disposed between the pixels 100 and connects the upper electrode 30 and a drive circuit to each other. As shown in FIGS. 6B and 6C, in the case where the upper electrode 30 and the high dielectric film 20 are also etched for the purpose of the device isolation, the width of the device isolation region 150 is widened, and the thickness of the stacked films subjected to the etching is thickened, and the large step difference occurs. The width of the device isolation region 150 in which the wire LA is disposed is particularly widened.

As obvious from comparison with the reflective light modulation device shown in FIGS. 6A to 6C, in the reflective light modulation device shown in FIGS. 5A and 5B, in which only the lower electrode 10 is isolated, the width of the device isolations 150 is narrower, and flatness thereof is better.

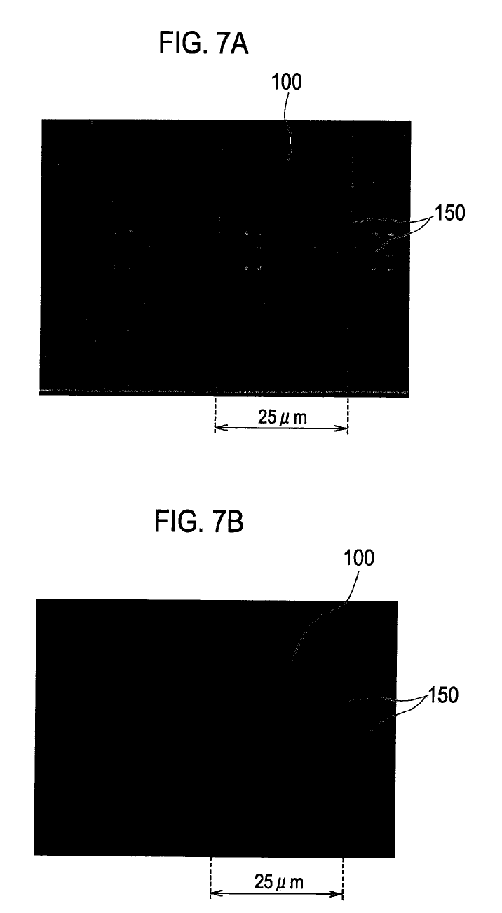

FIG. 7A shows a photograph example the upper surface of the reflective light modulation device in the case where only the lower electrode 10 is subjected to the device isolation by etching. Moreover, FIG. 7B shows a photograph example of the upper surface of the reflective light modulation device in the case where the upper electrode 30, the high dielectric film 20 and the lower electrode 10 are subjected to the device isolation by continuous etching. When FIG. 7A and FIG. 7B are compared with each other, an area of each device isolation region 150 is smaller in the case where only the lower electrode 10 is etched (FIG. 7A). Specifically, in the case where the middle between the device isolation regions 150 is defined as a boundary therebetween, and a ratio of a region serving as an output surface with respect to the device region is defined as an aperture ratio, an aperture ratio in the example shown in FIG. 7B is approximately 57%. Meanwhile, an aperture ratio in the example shown in FIG. 7A is approximately 89%. Specifically, in the reflective light modulation device in which only the lower electrode 10 is subjected to the device isolation by etching, the aperture ratio is enhanced by approximately 32% in comparison with the reflective light modulation device in which the high dielectric film 20 is isolated.

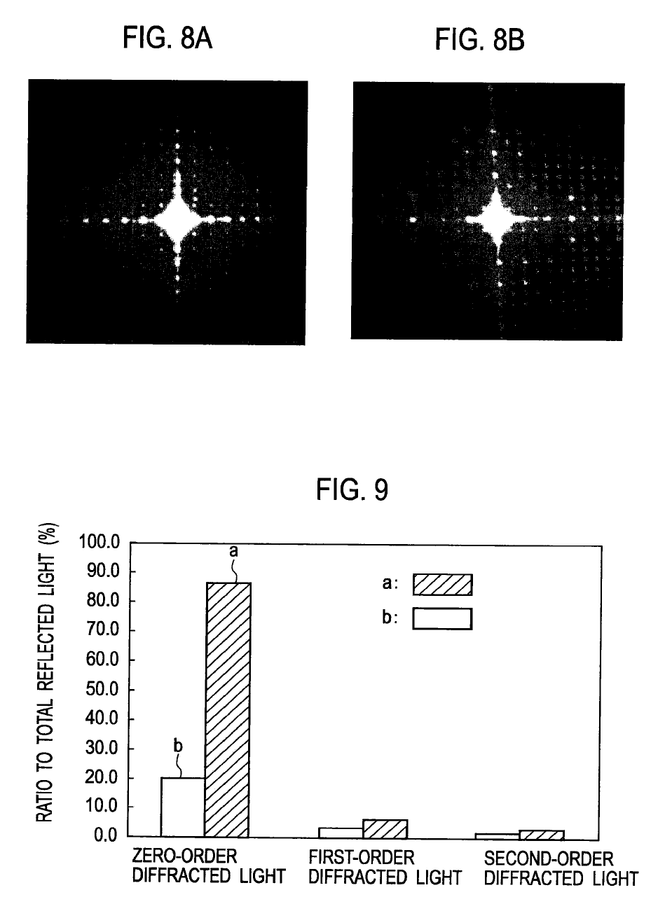

FIG. 8A shows a measurement example of a diffraction pattern of the reflective light modulation device in which only the lower electrode 10 is etched, and FIG. 8B shows a measurement example of a diffraction pattern of the reflective light modulation device in which the upper electrode 30, the high dielectric film 20 and the lower electrode 10 are etched continuously. The diffraction patterns shown in FIGS. 8A and 8B are obtained by measuring reflected lights in the case of irradiating the reflective light modulation devices with a laser having a wavelength of 532 nm. In FIGS. 8A and 8B, the brightest center portions are portions where zero-order diffracted lights are observed.

FIG. 9 shows ratios of zero-order to second-order diffracted lights with respect to total reflected light, which are obtained from the diffraction patterns shown in FIGS. 8A and 8B. In FIG. 9, graphs a show ratios of the zero-order to second-order diffracted lights in the case where only the lower electrode 10 is subjected to the device isolation by the etching, and graphs b show ratios of the zero-order to second-order diffracted lights in the case where the upper electrode 30, the high dielectric film 20 and the lower electrode 10 are subjected to the device isolation by the continuous etching. As shown in FIG. 9, the ratio of the zero-order diffracted light with respect to the total reflected light in the reflected light modulation device subjected to the device isolation by the continuous etching is approximately 20%. This is because scattering of the incident light occurs owing to irregularities generated on the reflective light modulation device, and light emitted from cut sections, and the like are increased. Meanwhile, the ratio of the zero-order diffracted light with respect to the total reflected light in the reflected light modulation device in which only the lower electrode 10 is subjected to the device isolation by the etching is approximately 87%. Specifically, in the reflected light modulation device in which only the lower electrodes 10 are formed by the etching, the ratio of the zero-order diffracted light with respect to the total reflected light is enhanced by approximately 4.3 times in comparison with the reflected light modulation device in which the upper electrode 30 and the high dielectric film 20 are also etched.

From the above-described measurement results, it has been recognized that, in the reflective light modulation device in which only the lower electrode 10 is subjected to the device isolation by the etching, since the high dielectric film 20 is not isolated, the occurrence of the light scattering is suppressed, and a good diffraction efficiency is brought. In particular, in the case where a film such as the PLZT film, which is difficult to etch, is adopted as the high dielectric film 20, it is not necessary to cut the high dielectric film 20. Accordingly, this results in simplification of the process, and the light scattering on the cut sections of the high dielectric film 20 is suppressed.

As described above, in the reflective light modulation device in which only the lower electrode 10 is subjected to the device isolation by the etching, the area of the device isolation regions is small, and the flatness is good. Therefore, the aperture ratio and the diffraction efficiency are enhanced.

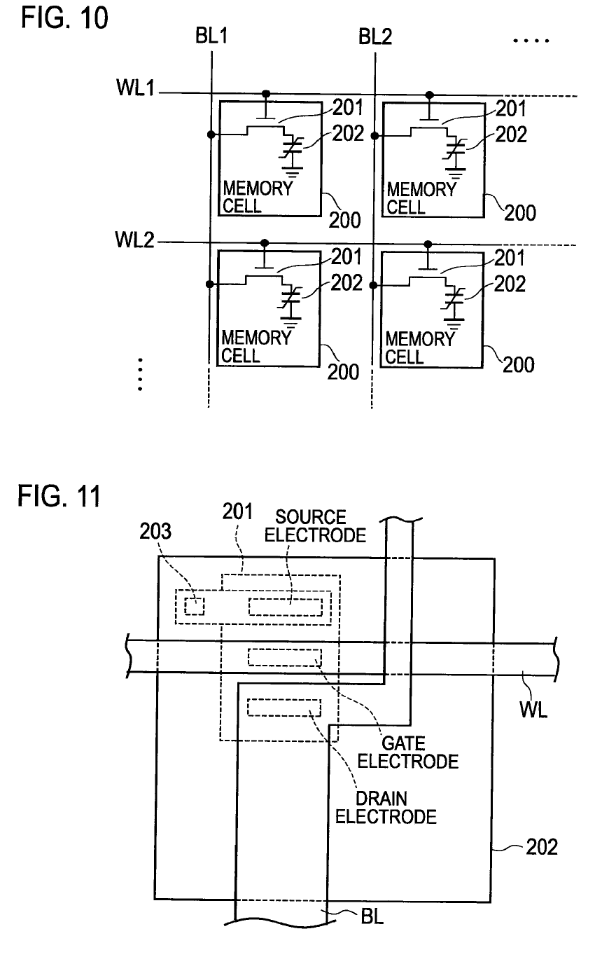

FIG. 10 shows an example where the high dielectric capacitors shown in FIG. 1 are used as capacitors of memory cells composing a memory cell array of a nonvolatile memory or the like. The memory cells shown in FIG. 10 include a plurality of bit lines BL₁, BL₂ . . . arrayed in a column direction, and a plurality of word lines WL₁, WL₂ . . . arrayed in a row direction perpendicular to the bit lines BL₁, BL₂ . . . . Then, the memory cells 200, each of which is controlled by any of the bit lines BL₁, BL₂ . . . and any of the word lines WL₁, WL₂ . . . , are arranged on the memory cell array in the matrix along the column direction and the row direction.

As shown in FIG. 10, each of the memory cells 200 includes a cell transistor 201 and a cell capacitor 202, which are serially connected to each other. Writing and reading to and from the memory cell 200 are controlled by the cell transistor 201. Gate electrodes and drain electrodes of the cell transistors 201 are connected to the word lines WL₁, WL₂ . . . and the bit lines BL₁, BL₂ . . . , respectively, and source electrodes of the cell transistors 201 are connected to one-side electrodes of the cell capacitors 202. The other-side electrodes of the cell capacitors are grounded. For example, the upper electrode 30 formed continuously in each of the memory cells 200 is used as such an electrode of the cell capacitor 202, which is to be grounded.

In each of the memory cells 200 using the high dielectric capacitors as the cell capacitors 202, data is memorized and stored by using a polarization phenomenon of the high dielectric film 20. The polarization state of the high dielectric film 20 is held even if the external electric field disappeared, and accordingly, the data memorized in the memory cell 200 is not lost even if the supply of the power supply was stopped. Therefore, a memory including the memory cells 200 using the high dielectric capacitors as the cell capacitors 202 operates as the nonvolatile memory.

As already described, in the high dielectric capacitors shown in FIG. 1, only the lower electrodes 10 are subjected to the device isolation by the etching, and accordingly, the area of the device isolation regions among the high dielectric capacitors can be reduced, and the high dielectric capacitors can be formed with good flatness. Hence, by using the high dielectric capacitors shown in FIG. 1 as the cell capacitors 202, the memory cell array can be formed with good flatness and an area of the memory cell can be small. Therefore, yield of the nonvolatile memory is enhanced.

The upper electrode 30 may be isolated into units of control and the like according to a circuit system and the like. Even in this case, the high dielectric film 20 difficult to etch is not isolated, and accordingly, a memory cell array with good flatness, for which fine isolation is possible, is realized.

FIG. 11 illustrates a plan view of a memory cell portion of the nonvolatile memory in which the high dielectric capacitors shown in FIG. 1 are adopted for the circuit shown in FIG. 10. FIG. 11 shows an example where the cell transistor 201 is disposed under the cell capacitor 202. As shown in FIG. 11, the one-side (lower-side) electrode of the cell capacitor 202 is connected to the source electrode of the cell transistor 201 through a via 203. Although not shown, the other-side (upper-side) electrode of the cell capacitor 202 is grounded. As already described, it is possible to continuously arrange such electrodes of the cell capacitors 202, which are to be grounded, over the plurality of memory cells 200. The gate electrode and drain electrode of each cell transistor 201 are connected to the word line WL and the bit line BL, respectively.

In the above description, the example has been shown, where the memory cell 200 is composed of one cell transistor 201 and one cell capacitor 202; however, it is a matter of course that other configurations may be adopted. For example, even in the case where the memory cell 200 is composed of two cell transistors 201 and two cell capacitors 202, the high dielectric capacitors are adoptable as the cell capacitors 202.

As described above, in the semiconductor device according to the first embodiment of the present invention, the upper electrode 30 is not isolated, the high dielectric film 20 is not isolated, and only the lower electrode 10 is isolated, whereby the device isolation is performed therefor. In such a way, such planarization and the fine isolation are possible. In particular, by the fact that the high dielectric film 20 is not isolated, a semiconductor device with good flatness, in which the step difference is small, is manufactured. As a result, for example, it becomes possible to enhance the aperture ratio and diffraction efficiency of the reflective light modulation device using the high dielectric capacitors with the structure shown in FIG. 1, to enhance the yield of the nonvolatile memory, and so on.

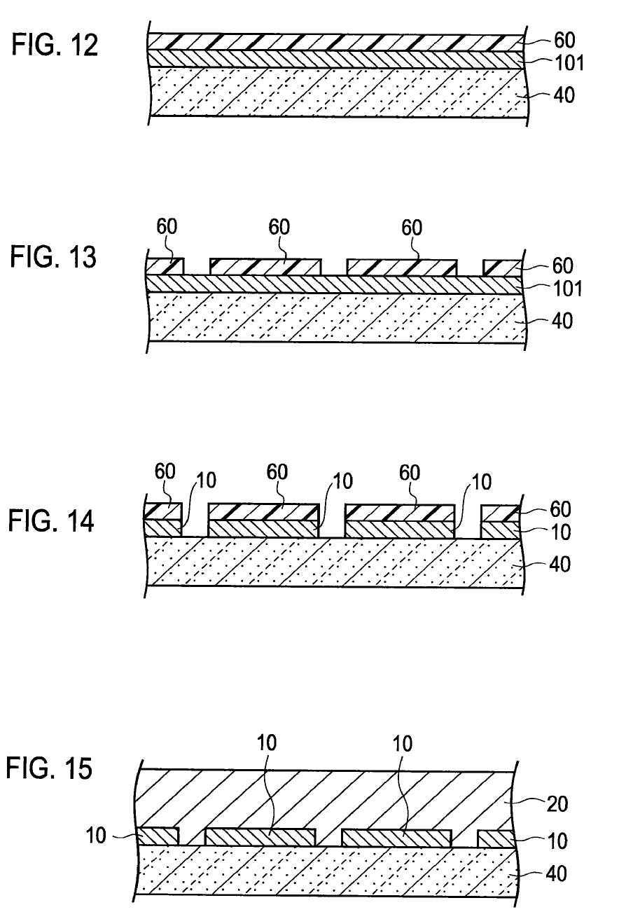

A description will be made of a manufacture method of the semiconductor device according to the first embodiment of the present invention with reference to FIGS. 12 to 15. The manufacture method of the semiconductor device, which will be described later, is an example, and it is a matter of course that the manufacture method concerned is realizable by other various manufacture methods including modification examples thereof.

(1) On the entire surface of the substrate 40, a lower electrode layer 101 made, for example, of Pt or Ir is formed at a film thickness of approximately 200 nm by the sputtering method and the like. Thereafter, as shown in FIG. 12, a photoresist film 60 is coated on the lower electrode layer 101.

(2) The photoresist film 60 is exposed and developed by the photolithography technology, whereby the photoresist film 60 on portions of the lower electrode layer 101, which become the device isolation regions, is removed.

(3) While using the photoresist film 60 as an etching mask, the lower electrode layer 101 is selectively etched by dry etching using chlorine gas and argon gas, whereby the plurality of lower electrodes 10 are formed as shown in FIG. 14.

(4) After the photoresist film 60 is removed, the high dielectric film 20 is formed on the lower electrodes 10. Specifically, the PLZT film or the like is formed at a film thickness of approximately 1 μm by using, for example, the sol-gel method and the like. At this time, the high dielectric film 20 is formed continuously on the plurality of lower electrodes 10 so that the regions among the lower electrodes 10 are filled with the high dielectric film 20. Thereafter, as shown in FIG. 15, the surface of the high dielectric film 20 is planarized by the chemical mechanical polishing (CMP) method and the like.

(5) On the high dielectric film 20, the upper electrode 30 made, for example, of Pt, Ir, IrO₂, SRO, ITO, ZnO or the like is formed at a film thickness of approximately 100 nm by the sputtering method. By the above-described steps, the semiconductor device shown in FIG. 1 is completed.

In the above description, the example of forming the high dielectric film 20 by the sol-gel method has been shown; however, the high dielectric film 20 may be formed by the sputtering method, the metal organic chemical vapor deposition (MOCVD) method and the like.

As described above, in the manufacture method of the semiconductor device according to the first embodiment of the present invention, the lower electrode 10 is isolated before forming the high dielectric film 20. Therefore, the device isolation can be performed without isolating the upper electrode 30 and the high dielectric film 20. Hence, even in the case of using, as the high dielectric film 20, the high dielectric film such as the PLZT film that is a substance difficult to etch, it is not necessary to isolate the high dielectric film difficult to etch, and the manufacture steps and the manufacture time can be reduced. Moreover, since it is not necessary to isolate the upper electrode 30 and the high dielectric film 20, it is possible to form the semiconductor device having the capacitor structure using the high dielectric film 20 so that the step difference can be small and that the flatness can be good, and the fine isolation of the semiconductor device is possible.

### Second Embodiment

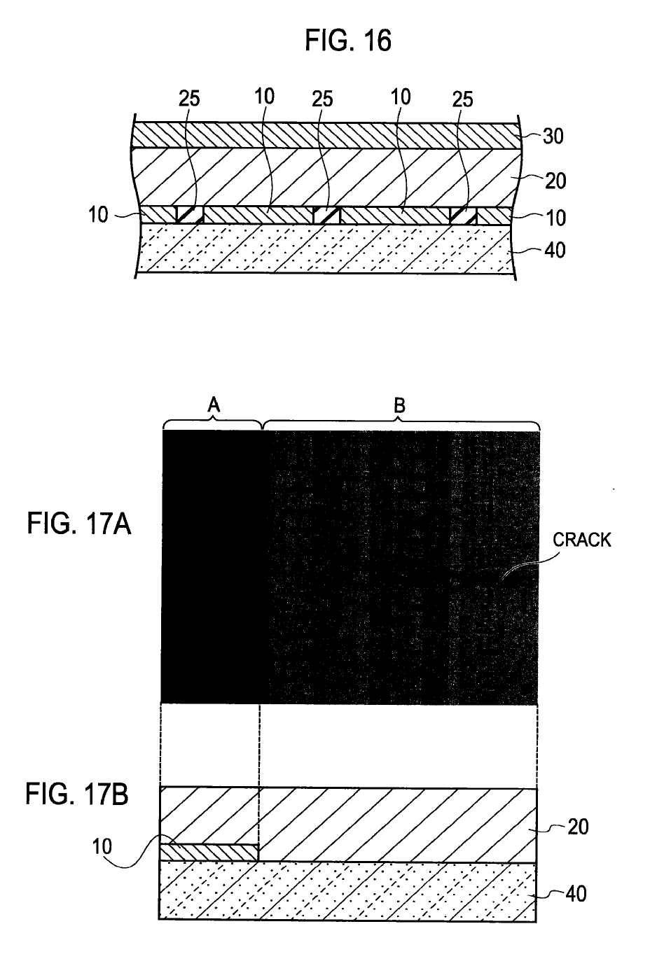

As shown in FIG. 16, a semiconductor device according to a second embodiment of the present invention is different from the semiconductor device shown in FIG. 1 in further including a barrier film 25 between the lower electrodes 10. Other configurations are similar to those of the first embodiment shown in FIG. 1.

In usual, in the case of forming the PLZT film having good characteristics on the substrate, it is preferable to form the PLZT film while allowing crystallinity of the substrate and crystallinity of the PLZT film to coincide with each other. This is because, in the case where crystal orientations of both of the above do not coincide with each other, it is apprehended that film shrinkage may occur while the PLZT film is being formed or in the heating process after forming the PLZT film, causing a crack in the PLZT film. Specifically, in some case, lead (Pd) atoms are diffused into the substrate from the PLZT film at the time of the heating process, and a composition of the PLZT film goes out of a stoichiometric composition thereof, and accordingly, the PLZT film cannot endure the film shrinkage, causing the crack. FIG. 17A shows an optical microscope photograph of an example of the crack that occurred in the PLZT film. FIG. 17A is a view of the PLZT film when viewed from a direction of the upper surface thereof, and FIG. 17B is a schematic view showing a cross section of the PLZT film. As shown in FIGS. 17A and 17B, no crack has occurred in the PLZT film in a region A where the PLZT film is disposed on the lower electrode 10, and the crack has occurred in the PLZT film in a region B where the PLZT film is directly disposed on the substrate 40.

Therefore, in the semiconductor device shown in FIG. 1, in the case of using the PLZT film as the high dielectric film 20, it is apprehended that the crack may occur in the high dielectric film 20 in regions in contact with the substrate 40 among the lower electrodes 10. However, as shown in FIG. 16, the barrier film 25 is disposed between the substrate 40 and the high dielectric film 20 in the regions among the lower electrodes 10, whereby such an occurrence of the crack in the PLZT film, which is caused by noncoincidence between the crystal orientations of the PLZT film and the substrate 40, can be prevented more surely.

Moreover, the barrier film 25 is formed as a dense layer that does not allow permeation of the Pd atoms and the like therethrough, whereby the Pd atoms can be prevented from being diffused from the PLZT film into the substrate 40. Here, the “dense layer” refers to a layer in which a crystal structure is dense, and for example in terms of a packing fraction, refers to a film or the like, in which a packing fraction is approximately 0.6 or more, while a packing fraction of an oxide film is approximately 0.5. For the barrier film 25, for example, an aluminum oxide (Al₂O₃) film, a silicon nitride (SiN) film and the like are adoptable.

In accordance with the semiconductor device according to the second embodiment of the present invention, the barrier film 25 is disposed between the substrate 40 and the high dielectric film 20 in the regions among the lower electrodes 10, whereby the occurrence of the crack in the high dielectric film 20 can be suppressed while enabling the planarization and the fine isolation. Moreover, the barrier film 25 also functions as a film which prevents the Pd atoms from being diffused from the PLZT film into the substrate 40. Others are substantially similar to those of the first embodiment, and a duplicate description will be omitted.

A description will be made below of a manufacture method of the semiconductor device according to the second embodiment of the present invention. The manufacture method of the semiconductor device, which will be described later, is an example, and it is a matter of course that the manufacture method concerned is realizable by other various manufacture methods including modification examples thereof.

(1) In a similar way to the method described with reference to FIGS. 12 to 14, the plurality of lower electrodes 10 are formed on the substrate 40 so as to be spaced from one another.

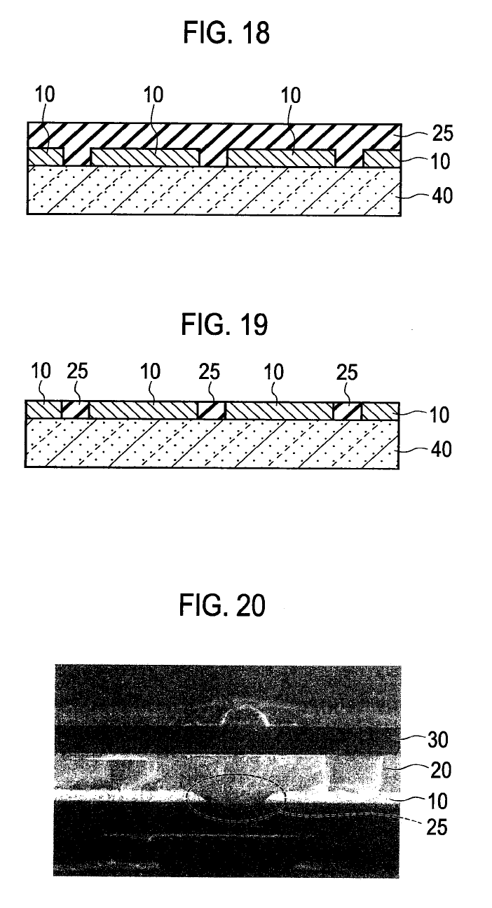

(2) As shown in FIG. 18, for example, the Al₂O₃ film or the like is formed as the barrier film 25 on the lower electrodes 10 and on the substrate 40 in the regions among the lower electrodes 10. Thereafter, a surface of the barrier film 25 is polished by the CMP method and the like until at least the surfaces of the lower electrodes 10 are exposed, whereby a structural cross section shown in FIG. 19 is obtained.

(3) The high dielectric film 20 and the upper electrode 30 are sequentially stacked on the lower electrodes 10 and the barrier film 25, whereby the semiconductor device shown in FIG. 16 is completed.

A film thickness of the barrier film 25 shown in FIG. 16 depends on the material of the barrier film 25 and the like; however, just needs to be a thickness sufficient for preventing the occurrence of the crack in the PLZT film and preventing the diffusion of the Pd atoms from the PLZT film into the substrate 40. For example, the film thickness just needs to be approximately several ten nanometers or more. FIG. 19 shows the case where an upper surface of the barrier film 25 and upper surfaces of the lower electrodes 10 are flush with each other in an illustrative manner; however, the film thickness of the barrier film 25 may be thinner than the film thickness of the lower electrodes 10, and the upper surface of the barrier film 25 may be positionally lower than the upper surfaces of the lower electrodes 10. FIG. 20 shows a microscope photograph of a cross section of the semiconductor device according to the second embodiment, which is manufactured by the above-described manufacture method.

As described above, in accordance with the manufacture method of the semiconductor device according to the second embodiment of the present invention, the barrier film 25 is formed among the lower electrodes 10 arranged so as to be spaced from one another. Therefore, the semiconductor device can be formed, in which the planarization and the fine isolation are enabled, the occurrence of the crack in the high dielectric film 20 is suppressed, and it is possible to prevent the Pd atoms from being diffused from the PLZT film into the substrate 40.

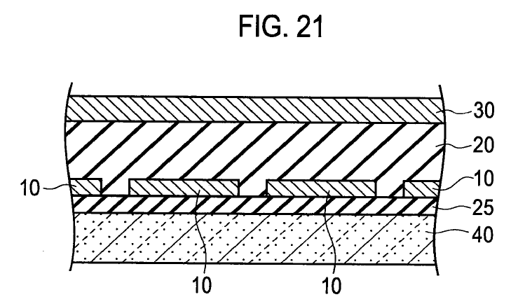

Moreover, as shown in FIG. 21, the barrier film 25 may be disposed on the entire surface of the substrate 40, and the plurality of lower electrodes 10 may be arranged on the barrier film 25. In a similar way to the semiconductor device shown in FIG. 1, in the semiconductor device shown in FIG. 21, the regions among the lower electrodes 10 are filled with the high dielectric film 20 disposed continuously on the lower electrodes 10. Also in the semiconductor device shown in FIG. 21, the high dielectric film 20 and the substrate 40 are not brought into contact with each other. Therefore, the occurrence of the crack in the high dielectric film 20 can be prevented more surely.

### Other Embodiments

In the already made description of the embodiment, the example where the upper electrode 30 is not isolated and the high dielectric film 20 is not isolated has been shown; however, the upper electrode 30 may be isolated according to needs. Even in this case, the high dielectric film 20 that is difficult to etch is not isolated, and accordingly, the semiconductor device with good flatness, for which the fine isolation is possible, is provided. Moreover, though the example where the high dielectric capacitors are applied to the reflective light modulation device has been shown, the present invention is applicable also to other spatial light modulators in each of which ON/OFF of pixels are controlled depending on a state of the capacitors.

Various modifications will become possible for those skilled in the art after receiving the teachings of the present disclosure without departing from the scope thereof.

What is claimed is:

1. A semiconductor device comprising:
a substrate;
a plurality of lower electrodes arranged on the substrate;
a high dielectric film disposed continuously on the plurality of lower electrodes; and
an upper electrode disposed on the high dielectric film.

2. The semiconductor device of claim 1, wherein the plurality of lower electrodes are arranged in a matrix pattern.

3. The semiconductor device of claim 1, wherein the high dielectric film is a lanthanum-doped lead zirconate titanate (PLZT) film.

4. The semiconductor device of claim 1, further comprising a barrier film disposed between the substrate and the high dielectric film in regions among the plurality of lower electrodes.

5. The semiconductor device of claim 4, wherein a packing fraction of the barrier film is 0.6 or more.

6. The semiconductor device of claim 1, wherein regions among the plurality of lower electrodes are filled with the high dielectric film.

7. The semiconductor device of claim 6, further comprising a barrier film disposed between the substrate and a group of the plurality of lower electrodes and the high dielectric film among the lower electrodes.

8. A method for manufacturing a semiconductor device, comprising:
forming a lower electrode layer on a substrate;
dividing the lower electrode layer into a plurality of lower electrodes;
forming a high dielectric film continuously on the plurality of lower electrodes; and
forming an upper electrode on the high dielectric film.

9. The method of claim 8, wherein the plurality of lower electrodes are arranged in a matrix pattern.

10. The method of claim 8, wherein the high dielectric film is a lanthanum-doped lead zirconate titanate (PLZT) film.

11. The method of claim 8, further comprising:
forming a barrier film between the substrate and the high dielectric film in regions among the plurality of lower electrodes.

12. The method of claim 11, wherein a packing fraction of the barrier film is 0.6 or more.

13. The method of claim 8, wherein regions among the plurality of lower electrodes are filled with the high dielectric film.

14. The method of claim 13, further comprising:
forming a barrier film between the substrate and a group of the plurality of lower electrodes and the high dielectric film among the lower electrodes.
